(19) United States
(12) Patent Application Publication
(10) Pub. No.: US 2015/0273654 A1
(43) Pub. Date: Oct. 1, 2015

(54) POLISH PAD, POLISH METHOD, AND METHOD OF MANUFACTURING SEMICONDUCTOR DEVICE

(71) Applicant: Kabushiki Kaisha Toshiba, Minato-ku (JP)

(72) Inventor: Shunsuke DOI, Yokkaichi (JP)

(73) Assignee: KABUSHIKI KAISHA TOSHIBA, Minato-ku (JP)

(21) Appl. No.: 14/448,358

(22) Filed: Jul. 31, 2014

(30) Foreign Application Priority Data
Mar. 26, 2014 (JP) 2014-063864

(51) Int. Cl. B24B 37/24; H01L 21/67; H01L 21/306; B24B 53/017; B24B 55/02

(52) U.S. Cl. CPC B24B 37/24; B24B 53/017; B24B 55/02; H01L 21/30625; H01L 21/67092; H01L 21/67075

(57) ABSTRACT

A polish pad for use in a chemical mechanical polishing including a polish layer having a polish surface configured to be capable of contacting a polish object, the polish layer including a coolant.

### CROSS-REFERENCE TO RELATED APPLICATION(S)

This application is based upon and claims the benefit of priority from Japanese Patent Application No. 2014-063864, filed on, Mar. 26, 2014 the entire contents of which are incorporated herein by reference.

### FIELD

Embodiments disclosed herein generally relate to a polish pad, a polish method, and a method of manufacturing a semiconductor device.

### BACKGROUND

Chemical mechanical polishing (CMP) is frequently used in semiconductor device manufacturing. Because the speed of chemical reaction varies with temperature in CMP, it is believed to be effective to control the surface temperature of the polish pad contacting the polish object such as a wafer to appropriate temperatures.

### BRIEF DESCRIPTION OF THE DRAWINGS

FIG. 1 is one example of a cross-sectional view schematically illustrating one embodiment of a polish pad.

FIG. 2 is one example of a chart indicating the temperature variation when ammonium nitrate is dissolved in water.

FIG. 3 is one example of a chart indicating a comparison of the cooling effects of urea, ammonium nitrate, and a mixture of urea and ammonium nitrate.

FIG. 4 schematically illustrates the structures of one example of a polish apparatus.

FIG. 5 is one example of a chart indicating the roughness of the polish surface of the polish pad.

FIG. 6 is one example of a cross-sectional view schematically illustrating the ground polish surface of the polish pad after being subjected to dressing.

FIGS. 7A to 7C are cross-sectional views illustrating one example of a manufacturing process flow of a semiconductor device and each illustrate one phase of the manufacturing process flow.

### DESCRIPTION

A polish pad for use in a chemical mechanical polishing including a polish layer having a polish surface configured to be capable of contacting a polish object, the polish layer including a coolant.

A method of polishing a polish object by a chemical mechanical polishing using a polish pad having a polish layer including a coolant, the polish layer having a polish surface being capable of contacting the polish object. The method includes polishing the polish object using the polish surface of the polish pad, and dressing, during or before the polishing, the polish surface of the polish layer to expose the coolant, the polish surface being cooled by the coolant.

A method of manufacturing a semiconductor device including forming a pattern above a semiconductor substrate; forming a polish object above the pattern; and polishing the polish object by chemical mechanical polishing using a polish pad having a polish layer including a coolant, the polish layer having a polish surface being capable of contacting the polish object to polish the polish object, dressing, during or before the polishing, the polish surface of the polish layer to expose the coolant, the polish surface being cooled by the coolant.

### Embodiments

A description will be given on the embodiments based on the accompanying figures.

First, a description is given on one embodiment of a polish pad.

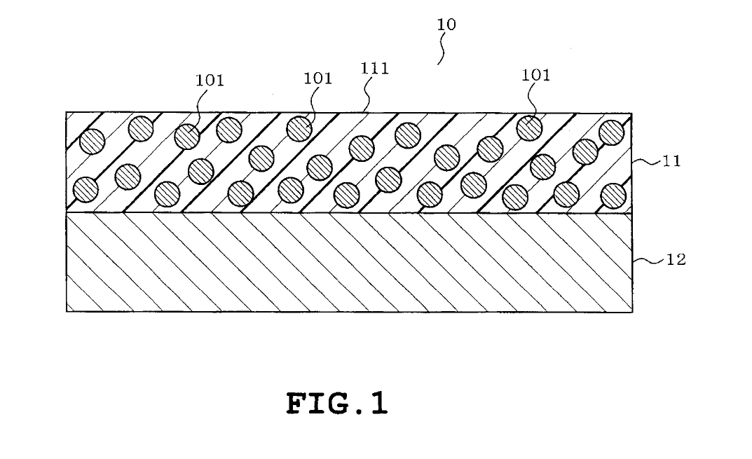

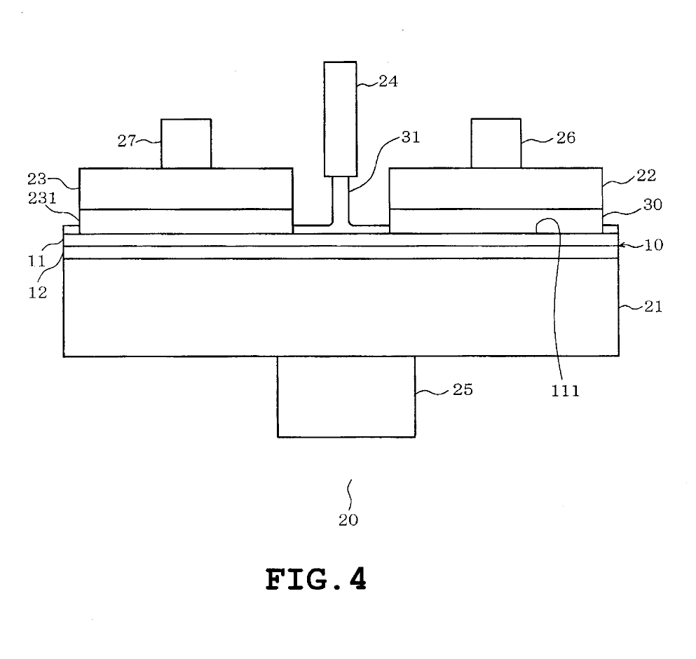

FIG. 1 illustrates polish pad 10 used for example in semiconductor device manufacturing. Polish pad 10 is attached to polish apparatus 20 illustrated in FIG. 4 for polishing wafer 30 by CMP (chemical mechanical polishing). Polish pad 10 is generally shaped like a disc and comprises a stack of pads varying in hardness. In one embodiment, polish pad 10 comprises a stack of main pad 11 and sub pad 12 as illustrated in FIG. 1.

Main pad 11 serves as a polish layer that polishes the polish object by physical contact. Sub pad 12 is slightly softer than main pad 11. Thus, sub pad 12 is prone to conform with the mating surface. For example, when polish pad 10 is attached to polish apparatus 20, sub pad 12 conforms with the undulations of the attachment interface of polish apparatus 20. This improves the polish uniformity. Though not shown, main pad 11 may be provided with holes and/or trenches for discharging slurry. In an alternative embodiment, polish pad 10 may be a single-layered pad and not a stack of pads.

In one embodiment, main pad 11 is primarily formed of for example a foamed polyurethane and sub pad 12 is primarily formed of for example a nonwoven fabric. Inside main pad 11, coolant 101 is provided which is shaped like a crystal grain. It is to be noted that the figures are not drawn to scale and the sizing of the coolant with respect to the polish pad is exaggerated in each figure. Coolant 101 is water soluble and absorbs heat through reaction with water. Coolant 101 is shaped regularly and in one embodiment, coolant 101 may be granular. In another embodiment, coolant 101 may be powder. The granular or powder coolant 101 is mixed evenly with uncured liquid polyurethane. Then, the polyurethane containing coolant 101 is hardened in a mold to obtain main pad 11.

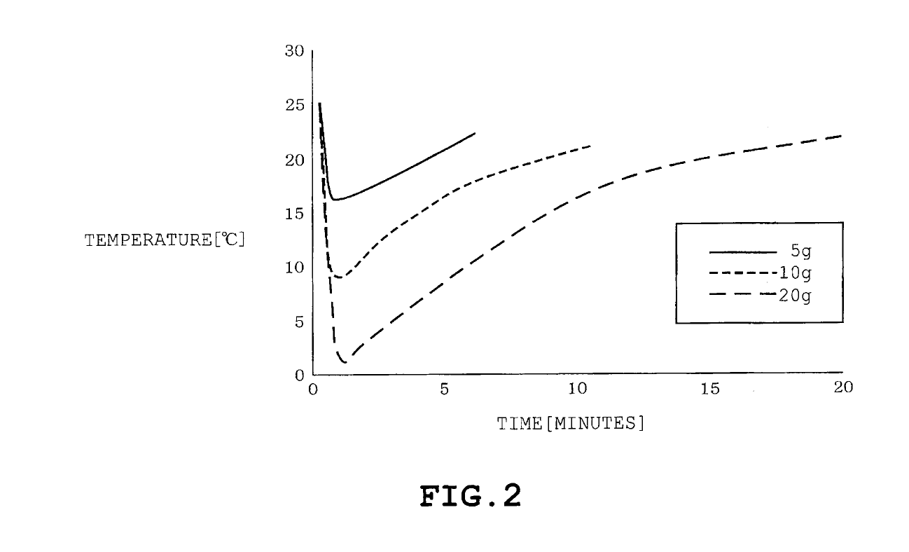

Examples of coolant 101 may be powder/granular ammonium nitrate or powder/granular urea. FIG. 2 indicates the variation in the temperature of water when 5 g, 10 g, and 20 g of ammonium nitrate is dissolved independently in 15 mL of water of 25 degrees Celsius. The temperature of water fell rapidly in about 1 minute after each quantity of ammonium nitrate was dissolved in the water. According to the chart indicated in FIG. 2, the temperature of water fell by approximately 10 degrees Celsius with 5 g of ammonium nitrate, approximately 15 degrees Celsius with 10 g, and approximately 20 degrees Celsius with 15 g. The results indicate that the cooling effect becomes greater as the quantity of ammonium nitrate dissolved in water increases.

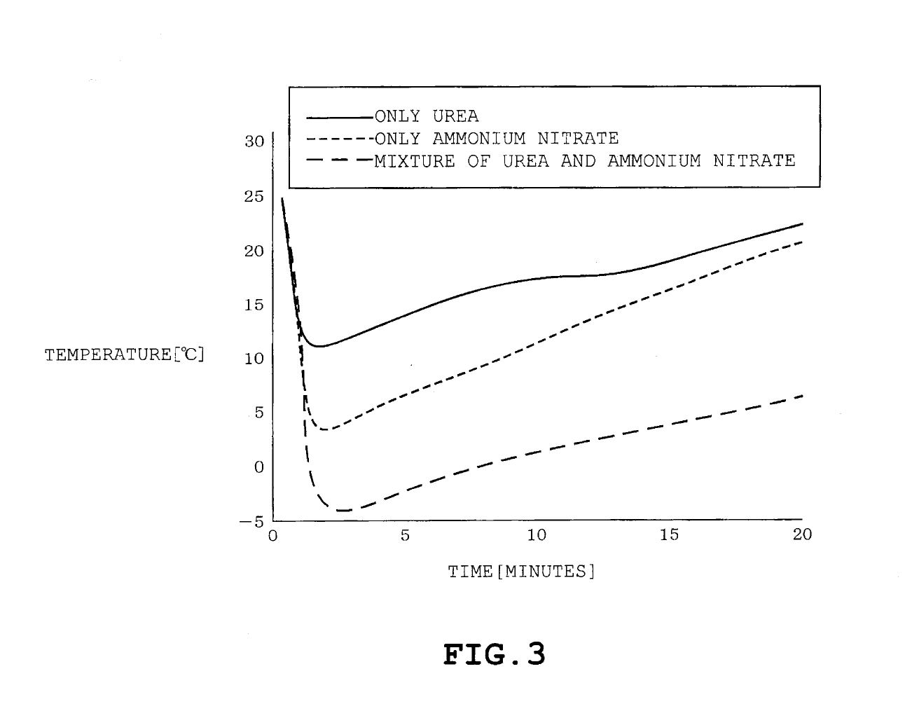

Yet, in another embodiment, coolant 101 may be a mixture of granular/powder ammonium nitrate or granular/powder urea. FIG. 3 indicates the variation in the temperature of water when a predetermined quantity (20 g) of coolant is dissolved in a predetermined quantity (15 mL) of water of 25 degrees Celsius. FIG. 3 indicates temperature variations when the coolant contains: (1) only ammonium nitrate, (2) only urea, and (3) a mixture of ammonium nitrate and urea in the ratio of 1:1, all of which may contain unavoidable impurities.

When the coolant contains only urea, the water temperature fell by approximately 15 degrees Celsius in about 1 minute after being dissolved in water. When the coolant contains only ammonium nitrate, the water temperature fell by approximately 20 degrees Celsius in about 1 minute after being dissolved in water. When the coolant is a mixture of urea and ammonium nitrate, the water temperature fell by approximately 30 degrees Celsius in about 1 minute after being dissolved in water. The results indicate that the cooling effect is greater when the coolant is a mixture of ammonium nitrate and urea as compared to when the coolant contains only ammonium nitrate or only urea. It was further found that the mixture of ammonium nitrate and urea exhibited a cooling efficiency approximately 1.5 times greater than the cooling efficiency of ammonium nitrate alone. The mixture ratio of ammonium nitrate and urea is controlled so that ammonium nitrate content ranges from 4 to 8 and urea content ranges from 6 to 2 in the mixture amounting to a mass of 10.

Other than those described above, materials of coolant 101 may include: ammonium metavanadate, ammonium chloride, ammonium bromide, ammonium iodide, sugar alcohol, inorganic ammonium salts such as ammonium sulfate, alkali metal salts such as sodium nitrate, potassium nitrate or potassium chloride.

Referring to FIG. 4, a brief description will be given on polish apparatus 20 to which polish pad 10 is attached. Polish apparatus 20 is provided with table 21, polish head 22, dresser 23, and slurry dispenser 24. Polish pad 10 is provided above table 21 so as to face polish head 22. Polish pad 10 is disposed so that main pad 11 serving as the polish layer faces upward toward polish head 22 and sub pad 12 faces downward toward table 21. The surface of main pad 11 serving as the polish layer and facing polish head 22 is referred to as polish surface 111. Table 21 is driven by table driver 25 so as to rotate with polish pad 10 disposed above it.

Polish head 22 is disposed so as to oppose polish pad 10 provided above table 21. Polish head 22 is disposed upward of table 21. Polish head 22 is disposed so as to be displaced toward a first side with respect to the rotational center of table 21. The polish object, which is wafer 30 in this example, is held at the underside of polish head 22 facing table 21. In FIG. 4, the thickness of wafer 30 with respect to the dimensions of other structures such as polish pad 10 is exaggerated from the actual thickness for visibility and better understanding. Polish head 22 applies force on wafer 30 held at its underside. Thus, wafer 30, being held by polish head 22, is pressed downward against polish surface 111 of polish pad 10. Polish head 22 is driven in rotation by polish head driver 26. As a result, wafer 30 rotates with polish head 22.

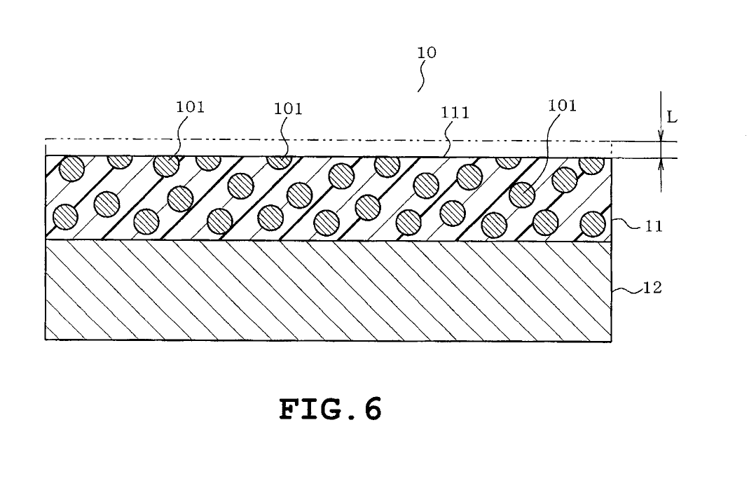

Dresser 23 is disposed so as to oppose polish pad 10 provided above table 21. Dresser 23 is provided upward of table 21. Dresser 23 is disposed so as to be displaced toward a second side with respect to the rotational center of table 21. In other words, dresser 23 is located on the opposite side of polish head 22 with respect to the rotational center of table 21. Dresser 23 is provided with dressing pad 231. Dresser 23 applies force on dressing pad 231 so as to press dressing pad 231 downward against polish surface 111 of polish pad 10. Dresser 23 is driven in rotation by dresser driver 27. Thus, dressing pad 231 rotates with dresser 23. As a result, dressing pad 231 grinds main pad 11, in other words, the polish layer of polish pad 10 to form a polish surface 111 in main pad 11. At this instance, coolant 101 within main pad 11 is exposed on polish surface 111 as illustrated in FIG. 6.

Slurry dispenser 24 supplies slurry 31 containing polish agent and water onto polish surface 111 of polish pad 10. Slurry 31 supplied from slurry dispenser 24 is fed between wafer 30 held by polish head 22 and polish surface 111 of polish pad 10 when polishing wafer 30. Wafer 30 held by polish head 22 is pressed against polish pad 10 with appropriate force. Thus, the surface of wafer 30 is polished by contact with polish surface 111 of polish pad 10.

Next, a description will be given on the method of polishing wafer 30 using polish pad 10 of one embodiment. When wafer 30 is polished by polish pad 10, the temperature of polish surface 111 of polish pad 10 is elevated by friction heat. Thus, in one embodiment, polish apparatus 20 performs a dressing process during or before the polishing process. The dressing process forms polish surface 111 by grinding the surface of main pad 11 which is configured to contact wafer 30. The dressing process further exposes coolant 101 within main pad 11 to polish surface 111. The polishing process polishes the polish object, wafer 30 in this case, with polish surface 111 of polish pad 10.

Coolant 101 exposed to polish surface 111 of polish pad 10 by the dressing process deprives heat from its surrounds in the polishing process through reaction with water contained in slurry 31 supplied from slurry dispenser 24. Coolant 101, exerting cooling effect in the above described manner, cools polish surface 111 of polish pad 10.

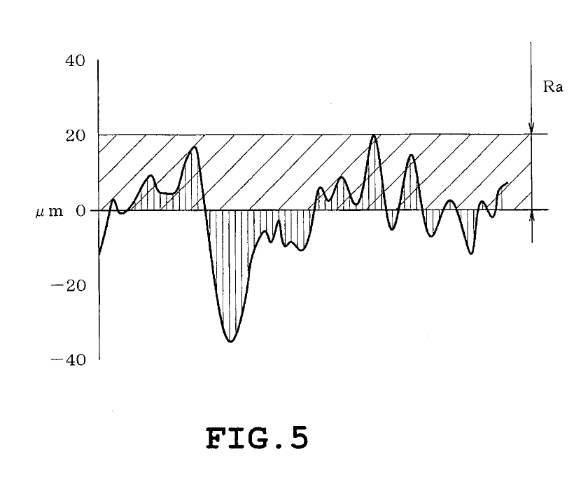

Grinding amount L of polish pad 10 in the dressing process may be obtained for example as follows. When radius R of main pad 11 is represented as R=37[cm], surface area S of main pad 11 can be obtained by S=πR²=4.3×10³[cm²]. Water contained in slurry 31 permeates into main pad 11 from polish surface 111. Thus, a mixture of urethane, being an ingredient of main pad 11, and water contained in slurry reside in the periphery of polish surface 111. In this example, it is assumed that water occupies 50% of the mixture. Further, as indicated in FIG. 5, it is assumed that calculated average surface-roughness Ra of polish surface 111 of main pad 11 is Ra=20 [μm]. In such case, volume W of water existing in polish surface 111 amounts to W=S×Ra×0.5=4.3 [cm³], meaning that approximately 4.3 g of water exists in the periphery of polish surface 111.

According to the chart indicated in FIG. 2, 5 g of ammonium nitrate is required to lower the temperature of 15 g of water by 10 degrees Celsius. Thus, amount M1 of ammonium nitrate required to lower the temperature of 4.3 g of water by 10 degrees Celsius is M1=(4.3/15)×5=1.43 [g]. As shown in FIG. 3, the cooling efficiency of the coolant containing the mixture of ammonium nitrate and urea is approximately 1.5 times higher than the cooling efficiency of the coolant containing only ammonium nitrate. Thus, amount M2 of the mixture of ammonium nitrate and urea required to lower the temperature of 4.3 g of water by 10 degrees Celsius is M2=1.43÷1.5=0.95[g]. As a result, 1 [g] coolant 101 containing the mixture of ammonium nitrate and urea is sufficient to lower the temperature of approximately 4.3 [g] of water, existing in the periphery of polish surface 111 of main pad 11, by 10 degrees Celsius.

Assuming that specific gravity is 1[g/cm²] respectively for urethane used in main pad 11 and for coolant 101, grinding amount L of main pad 11 in the dressing process for exposing 1 [g] of coolant 101 in polish surface 111 of main pad 11 is L=1/(S×0.5)=4.7 [μm]. Grinding amount L of polish pad 10 in the dressing process is obtained in the above described manner.

Next, a description will be given on a manufacturing process flow of a semiconductor device using polish pad 10.

Temperature elevation of the polish pad is typically observed during chemical mechanical polishing. The temperature elevation may lower the polish rate and/or soften the polish layer of the polish pad and consequently increase instances of erosion. Thus, temperature control of the polish pad may be effective in such cases. In the manufacturing process flow of a semiconductor device exemplified in the present embodiment, a dressing process is performed before or during the polishing process in which the polish object is polished by polish surface 111 of polish pad 10. As a result, coolant 101 within main pad 11 is exposed by the dressing and polish surface 111 is cooled by the exposed coolant 101. Temperature elevation of polish pad 10 is inhibited in the above described manner.

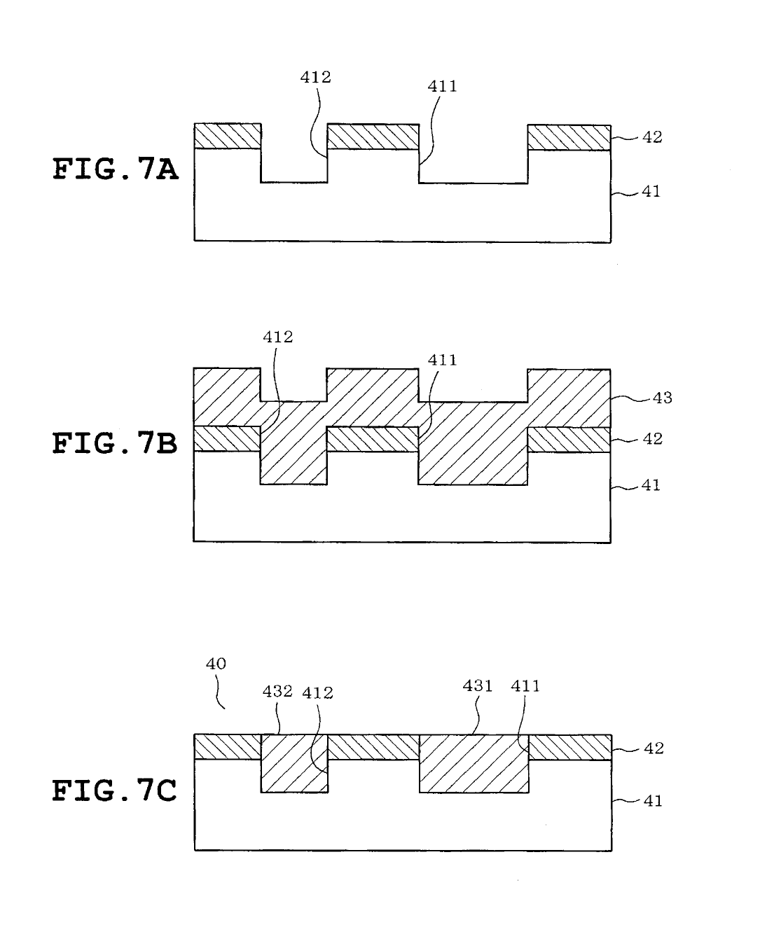

More specifically, silicon nitride film 42 being approximately 70 nm thick for example is formed above silicon substrate 41 as shown in FIG. 7A. Silicon nitride film 42 serves as a stopper film. Next, though not illustrated, silicon nitride film 42 and silicon substrate 41 are etched using a silicon oxide film or the like as an etch mask. As a result, trenches 411 and 412 for example having a depth of approximately 450 nm are formed as STI (shallow trench isolation) patterns. A silicon oxide film for example may be provided between silicon substrate 41 and silicon nitride film 42.

Then, as illustrated in FIG. 7B, silicon oxide film 43 is formed so as to fill trenches 411 and 412 of the STI pattern. Silicon oxide film 43 may be formed in the thickness of approximately 600 nm for example by methods such as high density plasma CVD (HDP-CVD). As illustrated in FIG. 7B, the surface of silicon oxide film 43 has a projecting and retracting profile defined by trenches 411 and 412.

Then, as illustrated in FIG. 7C, the polish object, which is silicon oxide film 43 in this example, is polished by chemical mechanical polishing using polish pad 10 and polish apparatus 20. As described earlier, the temperature of polish pad 10 is elevated during the polishing process. Thus, the so-called In-Situ dressing is performed in the present embodiment in which polish pad 10 is dressed during or before the polishing process. As a result, coolant 101 within main pad 11 of polish pad 10 is exposed during or before the polishing. Coolant 101 reacts with water contained in the slurry and absorbs heat to cool polish surface 111. Chemical mechanical polishing progresses in the above described manner to expose silicon nitride films 42. As a result, semiconductor device 40 is obtained in which trenches 411 and 412 are filled with silicon oxide films 431 and 432 as shown in FIG. 7C.

In the embodiment described above, polish pad 10 used in the chemical mechanical polishing is provided with main pad 11 serving as a polish layer having polish surface 111. Polish surface 111 is capable of contacting the polish object which is wafer 30 in this case. Main pad 11 serving as the polish layer contains coolant 101 inside it. Coolant 101 within main pad 11 absorbs heat through reaction with water contained in slurry 31. As a result, polish surface 111 of main pad 11 is cooled rapidly.

It is thus, possible to provide polish pad 10 capable of cooling polish surface 111 during the polishing process. In the above described configuration, polish surface 111 of polish pad 10 can be cooled in the polishing process without making cumbersome modifications to polish apparatus 20 such as providing an air-blower nozzle. In the present embodiment, polish surface 111 can be cooled during the polish process by merely providing polish pad 10 of the present embodiment to polish apparatus 20 instead of the conventional polish pad which does not exert cooling effect. Thus, polish surface 111 can be cooled easily in the polishing process.

Coolant 101 used in the present embodiment is water soluble and thus, dissolves in water contained in slurry 31 normally used in polishing wafer 30. Therefore, after coolant 101 has exerted its cooling effect, it may be discharged from polish pad 10 along with water contained in slurry 31. Thus, it is not required to provide a separate mechanism for discharging coolant 101.

Coolant 101 of the present embodiment absorbs heat through reaction with water. More specifically, coolant 101 is capable of absorbing heat and consequently exert a cooling effect by utilizing water contained in slurry 31 normally used in the polish process of wafer 30. Thus, polish surface 111 can be cooled with ease in the polishing process by using polish pad 10 of the present embodiment.

Coolant 101 of the present embodiment is regularly shaped. For example, coolant 101 may comprise a granular cooling agent. As a result, handling of coolant 101 in the manufacturing of main pad 11 becomes easier.

Further in the present embodiment, polish apparatus 20 performs a dressing process for dressing polish surface 111 of main pad 11 during or before the polish process in which the polish object i.e., wafer 30 is polished by polish surface 111. As a result, coolant 101 contained in main pad 11 is exposed to polish surface 111 by the dressing process performed during or before the polishing process. Thus, it becomes easier for coolant 101 to contact water contained in slurry 31 in the polish process and thereby more effectively exert the cooling effect of coolant 101. As a result, it is possible to inhibit polish rate degradation and/or increased instances of erosion caused by softening of main pad 11 serving as the polish layer of polish pad 10.

The process flow for manufacturing a semiconductor device of the present embodiment allows appropriate temperature control of polish surface 111 of polish pad 10. Thus, it is possible to inhibit degradation of polish rate and obtain uniformity in the surface of the semiconductor device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A polish pad for use in a chemical mechanical polishing comprising:
a polish layer having a polish surface configured to be capable of contacting a polish object, the polish layer including a coolant.

2. The polish pad according to claim 1, wherein the coolant is water soluble.

3. The polish pad according to claim 1, wherein the coolant reacts with water and absorbs heat.

4. The polish pad according to claim 1, wherein the coolant is shaped regularly.

5. The polish pad according to claim 1, wherein the coolant is granular.

6. The polish pad according to claim 2, wherein the coolant reacts with water and absorbs heat.

7. The polish pad according to claim 2, wherein the coolant is shaped regularly.

8. The polish pad according to claim 2, wherein the coolant is granular.

9. The polish pad according to claim 3, wherein the coolant is shaped regularly.

10. The polish pad according to claim 3, wherein the coolant is granular.

11. The polish pad according to claim 4, wherein the coolant is granular.

12. The polish pad according to claim 6, wherein the coolant is shaped regularly.

13. The polish pad according to claim 6, wherein the coolant is granular.

14. The polish pad according to claim 7, wherein the coolant is granular.

15. The polish pad according to claim 9, wherein the coolant is granular.

16. The polish pad according to claim 12, wherein the coolant is granular.

17. A method of polishing a polish object by a chemical mechanical polishing using a polish pad having a polish layer including a coolant, the polish layer having a polish surface being capable of contacting the polish object, comprising:
polishing the polish object using the polish surface of the polish pad, and
dressing, during or before the polishing, the polish surface of the polish layer to expose the coolant, the polish surface being cooled by the coolant.

18. A method of manufacturing a semiconductor device comprising:
forming a pattern above a semiconductor substrate;
forming a polish object above the pattern; and
polishing the polish object by chemical mechanical polishing using a polish pad having a polish layer including a coolant, the polish layer having a polish surface being capable of contacting the polish object to polish the polish object,
dressing, during or before the polishing, the polish surface of the polish layer to expose the coolant, the polish surface being cooled by the coolant.
